(19) United States
(12) Patent Application Publication
(10) Pub. No.: US 2015/0042349 A1
(43) Pub. Date: Feb. 12, 2015

(54) VOLTAGE MEASUREMENT

(71) Applicants: Huipeng Yang, Espoo (FI); Changjiang Zhang, Beijing (CN); Jianying Wen, Espoo (FI); Deshuai Yin, Beijing (CN)

(72) Inventors: Huipeng Yang, Espoo (FI); Changjiang Zhang, Beijing (CN); Jianying Wen, Espoo (FI); Deshuai Yin, Beijing (CN)

(73) Assignee: Nokia Corporation, Espoo (FI)

(21) Appl. No.: 14/362,600

(22) PCT Filed: Dec. 16, 2011
(86) PCT No.: PCT/CN2011/084119

§ 371 Date: Aug. 21, 2014

(51) Int. Cl. G01R 31/36

(52) U.S. Cl. CPC G01R 31/3606; G01R 31/3644
USPC 324/426

(57) ABSTRACT

Apparatus comprises a charging terminal for connection to a source of charging current; a battery terminal for connection to a battery; a first resistive element; a second resistive element; a switch having a single pole and first and second throws; and a voltage measurement circuit having first and second inputs. The first throw of the switch is coupled to a node between the battery terminal and the second resistive element. The second throw of the switch is coupled to a node between the charging terminal and the first resistive element. The first resistive element is coupled between the charging terminal and the second resistive element. The second resistive element is coupled between the battery terminal and the first resistive element. The pole of the switch is coupled to a first input of the voltage measurement circuit.

### FIELD OF THE INVENTION

The invention relates to voltage measurement and in particular, although not exclusively, to voltage measurement for estimating remaining battery capacity in portable devices.

### BACKGROUND TO THE INVENTION

It is common for portable devices to have a rechargeable battery and charging circuit.

Remaining battery capacity estimation can be performed in portable devices in a number of different ways. Remaining battery capacity estimation can be achieved using relatively inexpensive hardware although these solutions tend to be fairly inaccurate. This is especially the case for solutions that only rely on battery voltage detection. More accurate battery capacity estimation has required relatively expensive hardware such as current sense amplifiers and/or a dedicated analogue to digital converter or fuel gauge IC.

### SUMMARY OF THE INVENTION

A first aspect of the invention provides apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
   wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs.

The switch may comprise a control input and is configured to connect the pole and the second throw together when a charging voltage is present at the charging terminal. The control input of the switch may be coupled to a mid-point of a voltage divider that is coupled between the charging terminal and ground potential. Alternatively, the control input of the switch may be coupled to a controller that is configured to provide a control signal depending on whether charging is or is not required.

The apparatus may comprise a passing element coupled between the charging terminal and the first resistive element.

The voltage measurement circuit may comprise a comparator, for example a differential amplifier, having first and second inputs. An output of the comparator may be coupled to an input of an analogue to digital converter.

The voltage measurement circuit may form part of a power management unit.

The apparatus may comprise a converter configured to calculate current from signals provided by the voltage measurement circuit.

The apparatus may comprise an integrator configured to integrate measured voltage or calculated current. The apparatus may comprise a battery level calculation module configured to use the integrated voltage or current to calculate remaining capacity of a battery coupled to the battery terminal.

A second aspect of the invention provides a portable device comprising apparatus as above.

A third aspect of the invention provides a method of operating apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
   wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
   the method comprising using the measured voltage to calculate charging and discharging of a battery coupled to the battery terminal.

A fourth aspect of the invention provides a computer program comprising instructions that when executed by apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
   wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
   control the apparatus to perform the method above.

A fifth aspect of the invention provides a non-transitory computer-readable storage medium having stored thereon computer-readable code, which, when executed by computing apparatus comprising at least one processor, at least one memory having stored therein computer code, and:
a charging terminal for connection to a source of charging current;
a battery terminal for connection to a battery;
a first resistive element;
a second resistive element;
a switch having a single pole and first and second throws; and
a voltage measurement circuit having first and second inputs,
   wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
   causes the computing apparatus to perform a method comprising using the measured voltage to calculate charging and discharging of a battery coupled to the battery terminal.

### BRIEF DESCRIPTION OF THE DRAWINGS

FIG. 1 shows a circuit diagram of a circuit according to an exemplary embodiment of the invention; and

FIG. 2 shows a flowchart illustrating some aspects of operation of the FIG. 1 circuit.

### DETAILED DESCRIPTION OF EXEMPLARY EMBODIMENTS

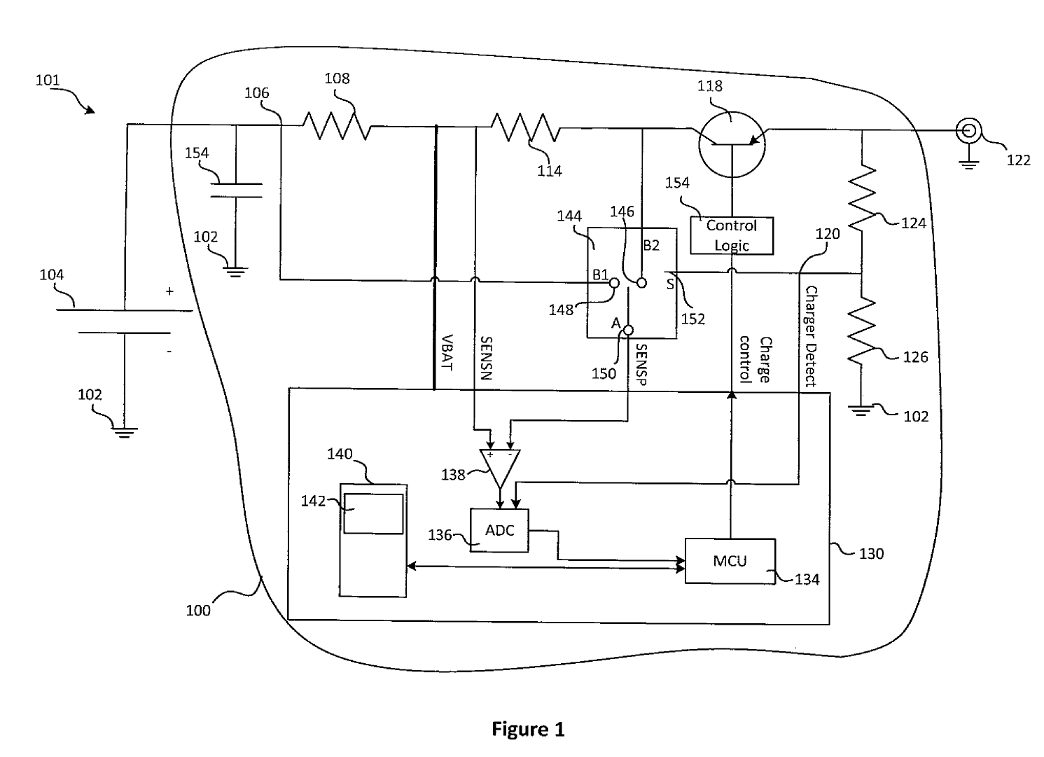

FIG. 1 shows a circuit 100 in a portable device 101. The circuit 100 includes a power management unit 130, details of which are described below. The device 101 includes a battery 104. The battery may be removably included within a housing (not shown) of the device 101 or it may be non-removable included. The device 101 also includes a charger connector which includes a charger terminal 122. The device 101 may be a mobile telephone, laptop computer, tablet computer, personal music player, camera, video camera or other such battery-powered portable device. The device 101 may or may not include a wireless transceiver. Other parts of the device 101 and the charger connector are omitted from the figure for clarity.

Three components of the circuit 100 are connected between the charger terminal 122 and the anode of the battery 104 in series. These components are a passing element 118, a first resistor 114 and a second resistor 108.

A control input of the passing element 118 is coupled to an output of a control logic module 154. A first main electrode of the passing element 118 is connected to the charger terminal 122. A second main electrode of the passing element 118 is connected to a first terminal of the first resistor 114. The second terminal of the first resistor 114 is connected to a first terminal of the second resistor 108. The second terminal of the second resistor 108 is connected to the anode of the battery 104. The cathode of the battery 104 is connected to earth or ground potential 102. A capacitor 154 has two terminals. One is connected to a node between the battery 104 and the second resistor 108. The other is connected to earth or ground potential 102. The capacitance of the capacitor 154 may be 10 μF or greater, for instance. The capacitor serves to smooth out spikes, and protects the battery 104 and the device 101.

A switch 144 has one pole 150 and first and second throws 146, 148. In an exemplary embodiment, the pole 150 is connected to a positive voltage-sensing line input (hereafter SENSP) of the Power Management Unit (PMU) 130. Alternatively, the pole 150 may be connected to the GPIO pin of the Base Board processor within the phone itself. The first throw 146 is coupled to the node between the passing element 118 and the first resistor 114. The second throw 148 is coupled to the node between the second resistor 108 and the battery 104. A control input of the switch 144 is connected to the mid point of a voltage divider formed by a third resistor 124 and a fourth resistor 126. These resistors 124, 126 are connected in series between the charger input 122 and ground potential 102.

A node between the first and second resistors 108, 114 has two connections thereto. One is a negative voltage-sensing line input (hereafter SENSN) to the PMU 130. The other is a battery voltage power input (hereafter VBAT) to the PMU 130. The PMU 130 draws current through VBAT as required by other components of the device 101.

The first and second resistors 114, 108 are low resistance value, high accuracy resistors. The first resistor 114 has a value here of 0.15 Ohms. The second resistor 108 also has a value of 0.15 Ohms. The first and second resistors may alternatively have other values. They may have different values.

In the PMU 130, a comparator or differential amplifier 138, for instance an operational amplifier, has two inputs. One input is the sensing line SENSN. The second input is the sensing line SENSP.

An output of the operational amplifier 138 is connected to an input of an analogue-to-digital signal converter 136. An output of the analogue-to-digital signal converter 136 is connected to an input of a MicroController Unit (MCU) 134. The MCU 134 is bidirectionally connected to a memory 140. The memory 140 has control software 142 stored therein. The memory 140 acts as transient memory for the MCU 134. Alternatively, the memory 140 may be provided as two separate memories, one for storage and one as a transient memory for use by the MCU 134 in executing the software 142. The MCU 134 functions as an integrator, as well as providing other functions.

The PMU 130 has an output connected to an input of the control logic 154. In an exemplary embodiment, this output is controlled by the MCU 134. A current sensing line 120, (hereafter Charger Detect), is connected to the node at the midpoint between the third resistor 124 and the fourth resistor 126. Charger Detect 120 is also is connected to an input of the MCU 134.

When the switch 144 is controlled to connect the pole 150 to the first throw 146, SENSN and SENSP are connected across the first resistor 114. When the switch 144 is controlled to connect the pole 150 to the second throw 148, SENSN and SENSP are connected across the second resistor 108.

The differential amplifier 138 provides an output that is dependent on the difference in voltage at the SENSN and SENSP lines. Thus, dependent on the position of the switch 144, the differential amplifier is provided with the voltage across the first resistor 114 or the voltage across the second resistor 108. The position of the switch 144 depends on whether the charger is in or not, as described below.

The gain of the differential amplifier 138 and the range of the ADC 136 are selected such that the maximum possible current that can flow through the first resistor 114 and/or the second resistor 108 produces a voltage that is slightly lower than the saturation voltage of the ADC 136.

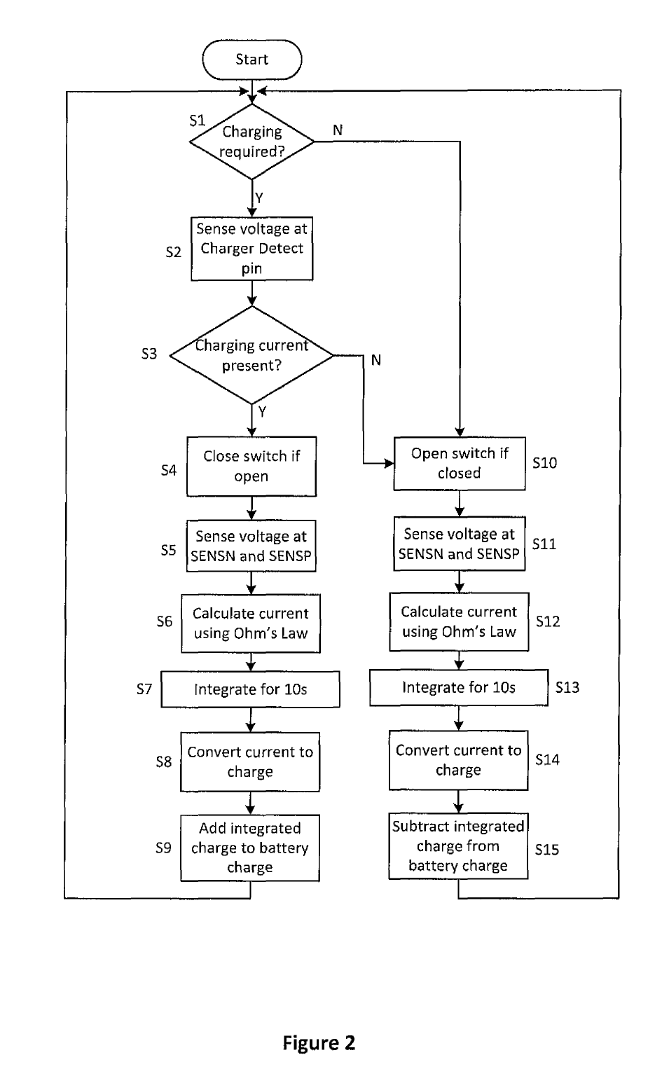

The operation of the FIG. 1 circuit will now be described with reference to FIG. 2. Details such as how the PMU 130 determines a battery full condition are not described here, although this and other usual functions are provided.

At step S1 the MCU 134 of the PMU 130 determines whether the battery 104 requires charging. This is achieved in any suitable way.

If the battery 104 does require charging, the method proceeds to step S2. Sensing line Charger Detect is used to determine whether there is a charging device connected to the charging terminal 122. If at step S3 there is no charging voltage at the charging terminal 122, as determined by the MCU 134 from the Charger Detect line 120, then no charging of the battery 104 can occur. If at step S3 the MCU 134 determines that no charger is connected, the method proceeds to step S10, described later. If a charging voltage is present, the method proceeds to step S4, as follows.

At this point it has been determined that the battery 104 does need charging and a charging voltage is present. In step S4, the MCU 134 causes the control logic 154 to close the passing element 118 or to remain closed if it was already closed. This allows charge to flows from the charging terminal 122 through the first and second resistors 114, 108 to the anode of the battery. The charging of the battery thus commences, if it was not already charging. Current from the charger terminal 122 flows to VBAT as required by the PMU 130, i.e. as the PMU draws current to power the PMU itself and also other components (transmitters, processors, etc.) of the device.

If there is a charging voltage at the charging terminal 122, a relatively high voltage is provided at the control input 152 of the switch 144 by the voltage divider 124, 126. This causes the switch 144 to connect the second throw 146 to the pole 150. This connects sensing line SENSP to the node between the passing element 118 and the first resistor 114.

At step S5, the voltage across the first resistor 114 is detected by the operational amplifier 138. This analogue voltage is converted to a digital signal level by the Analogue-to-Digital converter (ADC) 136. In step S5, the voltage across the first resistor 114 is sampled by the ADC 136.

At step S6 the MCU 134 calculates the current flowing through the first resistor 114 using Ohm's Law. At step S7 the current is integrated by the MCU 134 for a period of ten seconds. During this step, the ADC 136 samples the output of the differential amplifier at any suitable rate, for example 400 kHz. The ADC 136 may sample the detected voltage in every sampling period. Alternatively, the ADC 136 may sample the detected voltage in some of the sampling periods, and other sampling periods may be used for sampling voltages provided by other components. At step S9, the calculated charge is added to the initial charge of the battery, determined in step S1. This may involve subtracting a current estimated to have been drawn by the PMU 130. After the ten second window, the method repeats from step S1. The inclusion of a 10 second window is merely illustrative and the integration period may vary by implementation.

Following a negative determination from step S1 or step S3, the method proceeds to step S10. At step S10, the MCU 134 controls the control logic 154 not to connect the charging terminal 122 to the first resistor 114. If there is no charging voltage at the charger terminal 122, the control input 152 of the switch 144 receives a low voltage. This results from the voltage divider 124, 126 discharging any residual voltage that may have been at the charging terminal 122 when the charger was removed. The control input 152 receiving a low voltage causes the switch 144 to connect the second throw 148 to the pole 150, thus connecting SENSP to the node between the second resistor 108 and the battery 104. In this state, current drawn by the PMU 130 through the VBAT power line comes from the battery 104 and flows through the second resistor 108.

In step S11, the voltage across the second resistor 108 is sampled by the ADC 136. Steps S12 to S14 are the same as steps S5 to S8 respectively. At step S15, the calculated charge is subtracted from the calculated remaining battery capacity. The method then proceeds again to step S1.

The value of the second resistor 108 may be lower than the value of the first resistor 114. In devices in which the current drain may exceed the highest possible charge current, this provides an advantage in that the full dynamic range of the ADC 136 can be utilised to a greater extent for both charging and draining currents. This does, however, require adjustment of the values provided by the ADC 136 to the MCU 134 depending on whether the battery is charging so that the MCU can correctly calculate the change in charge over time.

Advantages can be realised by one or more of the example embodiments. For instance, charging current and current drawn from the battery can be calculated using only one ADC. Moreover, this is achieved with a relatively low hardware cost, perhaps only a resistor and a double throw switch. Of further note is the fact that this ADC can be incorporated within the PMU 130 and does not need to be provided as an external (to the PMU) element.

Disadvantages can also be experienced by one or more of the example embodiments. In particular, the voltage available at VBAT is lower than a case where VBAT is connected directly to the anode of the battery. In the case of a 0.15 Ohm resistor, the voltage drop across the second resistor 108 is 300 mV for a 2 A drain. This reduction in voltage overhead can be a significant disadvantage in some situations. This arrangement also provides power loss through the resistor 108. This is disadvantageous in that it is a waste of charge stored in the battery 104, reducing charging intervals and reducing the life span of the battery. It also provides some heating, for which heatsink provision needs to be made in the design of the device 101. These disadvantages can be ameliorated by providing the second resistor 108 with a smaller value. The use of a smaller value resistor reduces the accuracy of measurement of current draw at low currents, so ultimately the choice of value for the resistor is a trade-off between a requirement for accuracy and efficiency of utilisation of battery charge.

The resistors 114, 108 can be termed resistive elements and may take any suitable form. For instance they may be metal plate or thick film ceramic resistors. They may be surface mount devices. They may have tolerance to high temperatures. They may have low temperature coefficients, so that their resistance does not alter significantly with changes in temperature. They may be high precision resistors in that their resistance is within a very narrow range.

The passing element 118 may be any suitable element. For instance, it may be any suitable type of controllable switch, such as a bipolar transistor or FET. The passing element may be on-off in the sense that it may allow or block current. Alternatively, it may be controllable so as to limit current to a non-zero value that is less that the maximum possible current. In some exemplary embodiments, the passing element 118 may be omitted.

The switch 144 may take any suitable form. It is typically implemented as a transistor switching circuit.

The MCU may be any suitable microcontroller. The MCU may have the memory 140 integrated therein. The MCU may alternatively be replaced with a processor having more processing capability than would normally be found with a standard MCU.

1-15. (canceled)

16. An apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs.

17. The apparatus as claimed in claim 16, wherein the switch comprises a control input and is configured to connect the pole and the second throw together when a charging voltage is present at the charging terminal.

18. The apparatus as claimed in claim 17, wherein the control input of the switch is coupled to a mid-point of a voltage divider that is coupled between the charging terminal and ground potential.

19. The apparatus as claimed in claim 17, wherein the control input of the switch is coupled to a controller that is configured to provide a control signal depending on whether charging is or is not required.

20. The apparatus as claimed in claim 16, further comprising a passing element coupled between the charging terminal and the first resistive element.

21. The apparatus as claimed in claim 16, wherein the voltage measurement circuit comprises a comparator, for example a differential amplifier, having first and second inputs.

22. The apparatus as claimed in claim 21, wherein an output of the comparator is coupled to an input of an analogue to digital converter.

23. The apparatus as claimed in claim 16, wherein the voltage measurement circuit forms part of a power management unit.

24. The apparatus as claimed in claim 16, further comprising a converter configured to calculate current from signals provided by the voltage measurement circuit.

25. The apparatus as claimed in claim 16, further comprising an integrator configured to integrate measured voltage or calculated current.

26. The apparatus as claimed in claim 25, comprising a battery level calculation module configured to use the integrated voltage or current to calculate remaining capacity of a battery coupled to the battery terminal.

27. A method of operating apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
the method comprising using the measured voltage to calculate charging and discharging of a battery coupled to the battery terminal.

28. The method of claim 27, wherein the switch comprises a control input and is configured to connect the pole and the second throw together when a charging voltage is present at the charging terminal.

29. The method of claim 28, wherein the control input of the switch is coupled to a mid-point of a voltage divider that is coupled between the charging terminal and ground potential.

30. The method of claim 28, wherein the control input of the switch is coupled to a controller that is configured to provide a control signal depending on whether charging is or is not required.

31. The method of claim 27, further comprising determining current from signals provided by the voltage measurement circuit.

32. The method of claim 27, further comprising integrating measured voltage or calculated current.

33. The method of claim 32, further comprising determining remaining capacity of a battery coupled to the battery terminal based at least in part on the integrated voltage or current.

34. A computer program comprising instructions that when executed by apparatus comprising:
a charging terminal for connection to a source of charging current;
a battery terminal for connection to a battery;
a first resistive element;
a second resistive element;
a switch having a single pole and first and second throws; and
a voltage measurement circuit having first and second inputs,
wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
control the apparatus to perform the method of claim 28.

35. A non-transitory computer-readable storage medium having stored thereon computer-readable code, which, when executed by computing apparatus comprising at least one processor, at least one memory having stored therein computer code, and:
a charging terminal for connection to a source of charging current;
a battery terminal for connection to a battery;
a first resistive element;
a second resistive element;
a switch having a single pole and first and second throws; and
a voltage measurement circuit having first and second inputs,
wherein:
the first throw of the switch is coupled to a node between the battery terminal and the second resistive element,
the second throw of the switch is coupled to a node between the charging terminal and the first resistive element,
the first resistive element is coupled between the charging terminal and the second resistive element,
the second resistive element is coupled between the battery terminal and the first resistive element,
the pole of the switch is coupled to a first input of the voltage measurement circuit,
the second input of the voltage measurement circuit is coupled to a node between the first and second resistive elements, and
the voltage measurement circuit is configured to measure a voltage across its first and second inputs,
causes the computing apparatus to perform a method comprising using the measured voltage to calculate charging and discharging of a battery coupled to the battery terminal.
